(19) United States
(12) Patent Application Publication
(10) Pub. No.: US 2012/0193656 A1
(43) Pub. Date: Aug. 2, 2012

(54) DISPLAY DEVICE STRUCTURE AND MANUFACTURING METHOD THEREOF

(75) Inventors: Shih-Hao Tseng, Tainan City (TW); Shih-Hsing Hung, Hsinchu County (TW); Chih-Jen Hu, Hsinchu City (TW)

(73) Assignee: AU OPTRONICS CORPORATION, Hsinchu (TW)

(21) Appl. No.: 13/441,910

(22) Filed: Apr. 8, 2012

Related U.S. Application Data
(63) Continuation-in-part of application No. 13/093,835, filed on Apr. 25, 2011.

(30) Foreign Application Priority Data
Dec. 29, 2010 (TW) 99146603
Dec. 9, 2011 (TW) 100145567

(51) Int. Cl. H01L 33/08

(52) U.S. Cl. 257/88; 438/34; 257/E33.012

(57) ABSTRACT

A display device structure includes an active device, a passivation layer, a pixel electrode and a first conductive material. The passivation layer covers the active device and has a first through hole exposing a portion of the active device. The pixel electrode is disposed on the passivation layer, and the pixel electrode is a non-thin-film electrode consituted by a plurality of micro-conductive structures or includes an organic conductive polymer material. The first conductive material is disposed around the first through hole and electrically connected to the exposed active device. The pixel electrode is electrically connected to the first conductive material.

### CROSS-REFERENCE TO RELATED APPLICATION

This application is a continuation-in-part application of and claims the priority benefit of a prior application Ser. No. 13/093,835, filed on Apr. 25, 2011, now pending. The prior application Ser. No. 13/093,835 claims the priority benefit of Taiwan application serial no. 99146603, filed on Dec. 29, 2010. This application claims the priority benefit of Taiwan application serial no. 100145567, filed on Dec. 9, 2011. The entirety of each of the above-mentioned patent applications is hereby incorporated by reference herein and made a part of this specification.

### BACKGROUND OF THE INVENTION

1. Field of the Invention

The invention relates to a display device structure and a manufacturing method thereof, and particularly to a display device structure of a display and a manufacturing method thereof.

2. Description of Related Art

With the rapid development of display technologies, conventional cathode ray tube (CRT) displays have been gradually replaced by flat panel displays (FPD). In comparison with the FPD formed by a rigid carrier (e.g. a glass substrate), a flexible display in which an active device is formed on a flexible substrate has been developed according to recent researches because the flexible substrate (e.g. a plastic substrate) is characterized by flexibility and impact endurance.

Generally, the display is formed through a plurality of pixel structures, wherein each pixel structure includes a thin film transistor (TFT) and a pixel electrode electrically connected to the TFT. Regarding transmissive type display panels, pixel electrodes usually adopt an indium tin oxide (ITO) transparent electrode material. In conventional methods of forming pixel electrodes, a deposition method is used to form an ITO film, and then photolithography or etching is used to pattern the ITO film, to form each pixel electrode pattern.

However, since ITO is an inorganic oxide, the material is brittle. Thus, if the ITO film is applied in the pixel electrodes of a flexible display, it is prone to crack, causing the pixel structure unable to operate normally.

### SUMMARY OF THE INVENTION

The invention provides a display device structure and a manufacturing method thereof that can avoid pixel electrodes of a flexible display from cracking.

The invention provides a display device structure including an active device, a passivation layer, a pixel electrode, and a first conductive material. The passivation layer covers the active device, and the passivation layer has a first through hole exposing a portion of the active device. The pixel electrode is disposed on the passivation layer, wherein the pixel electrode is a non-thin-film electrode constituted by a plurality of micro-conductive structures or includes an organic conductive polymer material. The first conductive material is disposed around the first through hole and is electrically connected to the exposed active device, wherein the pixel electrode is electrically connected to the first conductive material.

The invention provides a manufacturing method of a display device structure. The method includes forming an active device on a substrate. A passivation layer is formed on the substrate to cover the active device. A first through hole is formed in the passivation layer to expose a portion of the active device. A pixel electrode is formed on the passivation layer, wherein the pixel electrode is a non-thin-film electrode made up by a plurality of micro-conductive structures or includes an organic conductive polymer material. A first conductive material is formed around the first through hole, wherein the first conductive material is electrically connected to the exposed active device, and the pixel electrode is electrically connected to the first conductive material.

A bonding pad structure including a bonding pad, a passivation, a contact pattern and a conductive material is provided. The passivation layer covers the bonding pad and has at least one through hole exposing the bonding pad. The contact pattern is located on the passivation, wherein the contact pattern is a non-thin-film electrode made up by a plurality of micro-conductive structures. The conductive material is disposed around the through hole and is electrically connected to the exposed pad, wherein the contact pattern is electrically connected to the conductive material.

Based on the above, the invention adopts the non-thin-film electrode formed by micro-conductive structures or the organic conductive polymer material as the pixel electrode, and the pixel electrode is electrically connected to the active device through the first conductive material. In addition, the invention also adopts the non-thin-film electrode formed by micro-conductive structures as the contact pattern of the bonding pad structure. Since the pixel electrode that is a non-thin-film electrode formed by micro-conductive structures or the organic conductive polymer material is flexible, when applied in a flexible display, there will be no cracking problem. Furthermore, in the invention, since the pixel electrode is electrically connected to the active device through the first conductive material, the pixel electrode will have no problem being in electrical contact with the active device even though it is a non-thin-film electrode.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional view of a display device structure according to an embodiment of the invention.

FIG. 2A to FIG. 2C are schematic top views of a through hole of a display device structure according to multiple embodiments of the invention.

FIG. 3 is a schematic cross-sectional view of a display device structure according to an embodiment of the invention.

FIG. 4 is a schematic cross-sectional view of a display device structure according to an embodiment of the invention.

FIG. 5 is a schematic top view of a bonding pad electrode structure according to an embodiment of the invention.

FIG. 6 is a schematic cross-sectional view taken along a sectional line A-A′ depicted in FIG. 5.

FIG. 7 and FIG. 8 are schematic cross-sectional views of a bonding pad according to embodiments of the invention.

FIG. 9 is a schematic top view of a display device structure according to an embodiment of the invention.

FIG. 10A is a schematic cross-sectional view of a display device structure in a display region according to an embodiment of the invention.

FIG. 10B is a schematic cross-sectional view of a display device structure in a bonding region according to an embodiment of the invention.

FIG. 10C is a schematic top view showing a display device structure in a region R of FIG. 10A.

FIG. 11A is a schematic cross-sectional view of a display device structure in a display region according to an embodiment of the invention.

FIG. 11B is a schematic cross-sectional view of a display device structure in a bonding region according to an embodiment of the invention.

FIG. 11C is a schematic top view showing a display device structure in a region R of FIG. 11A.

FIG. 12A is a schematic cross-sectional view of a display device structure in a display region according to an embodiment of the invention.

FIG. 12B is a schematic cross-sectional view of a display device structure in a bonding region according to an embodiment of the invention.

FIG. 12C is a schematic top view showing a display device structure in a region R of FIG. 12A.

FIG. 13A is a schematic cross-sectional view of a display device structure in a display region according to an embodiment of the invention.

FIG. 13B is a schematic cross-sectional view of a display device structure in a bonding region according to an embodiment of the invention.

FIG. 13C is a schematic top view showing a display device structure in a region R of FIG. 13A.

FIG. 14 is a schematic cross-sectional view of a display device structure according to an embodiment of the invention

### DESCRIPTION OF EMBODIMENTS

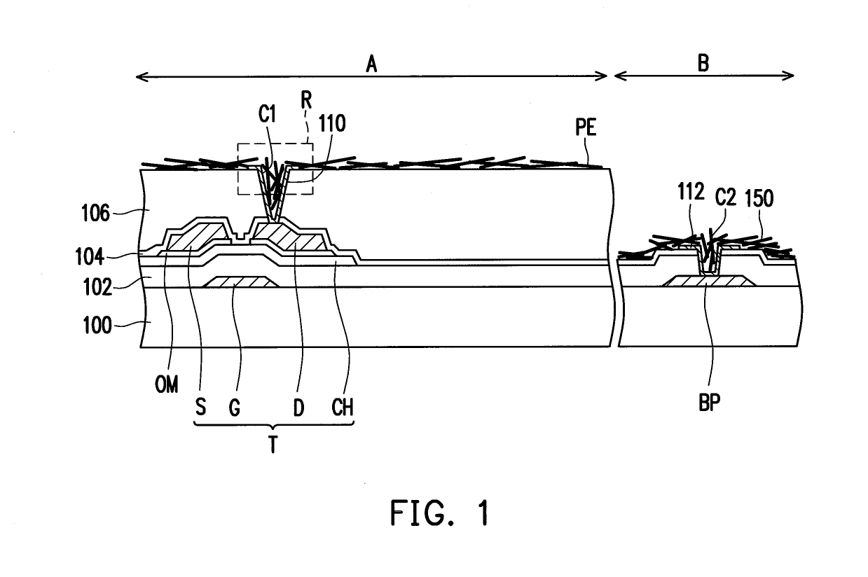

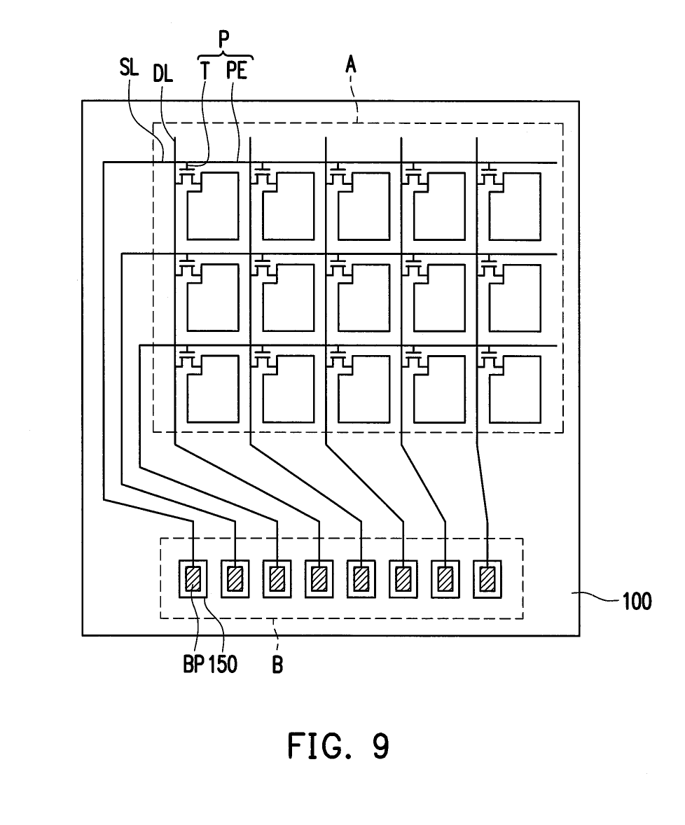

FIG. 1 is a schematic cross-sectional view of a display device structure according to an embodiment of the invention. FIG. 9 is a schematic top view of a display device according to an embodiment of the invention. Referring to FIG. 1 and FIG. 9, a manufacturing method of a display device structure of the embodiment at first provides a substrate 100. According to the embodiment, the substrate 100 has a display area A and a bonding area B.

The material of the substrate 100 can be glass, quartz, an organic polymer, or a non-light-transmissive/reflective material (such as a conductive material, metal, wafer, ceramics, or other suitable materials), or other suitable materials. If a conductive material or a metal is used, then the substrate 100 is covered with an insulating layer (not shown) to prevent short circuiting.

Next, an active device T is formed in the display area A of the substrate 100. The active device T includes a gate G, a channel CH, a source S, and a drain D. The gate G is electrically connected to a scan line SL, and the source S is electrically connected to a data line DL. In general, the active device T includes a bottom gate device or a top gate device. These two types of active devices are distinguished by the channel CH being disposed on the top or bottom of the gate G. In the bottom gate device, the channel CH is disposed on the gate G. In the top gate device, the channel CH is disposed under the gate G. The active device T of the embodiments of the invention is, for example, a bottom gate device, however, the active device T may also be a top gate device. Thus, the active device T of the invention is described as, for example, a bottom gate device. The gate G is disposed on the substrate 100, and when forming the gate G, generally, the scan line SL electrically connected to the gate G is simultaneously formed on the substrate 100. In addition, an insulating layer 102 covers the gate G, and the insulating layer 102 is referred to as a gate insulating layer. The channel CH is located on the insulating layer 102 above the gate G. The source S and the drain D are disposed on the channel CH. When the source S is formed, the data line DL electrically connected to the source S is simultaneously formed. In addition, an ohmic contact layer OM is formed between the channel CH and the source S/drain D.

According to an embodiment of the invention, when the active device T is formed in the display area A of the substrate 100, a bonding pad electrode BP is further simultaneously formed in the bonding area B of the substrate 100. The bonding pad electrode BP can be in the same layer with the gate G, or in the same layer with the source S/drain D. The bonding pad electrode BP of the figure of the embodiment is described as, for example, in the same layer with the gate G, but is not limited thereto.

After forming the active device T, passivation layers 104, 106 are formed on the substrate 100, to cover the active device T. According to the embodiment, the passivation layer 104 can be a single layer structure or a multiple layer structure, and the material of the passivation layer 104 comprises an inorganic material (e.g. silicon oxide, silicon nitride, silicon oxynitride, other suitable materials, or a combination of the above materials) or an organic material (e.g. polyester, polyethylene, cycloolefin, polyimide, polyamide, polyalcohols, polyphenylene, polyether, polyketone, other suitable materials, or a combination thereof). The passivation layer 106 can be a single layer structure or a multiple layer structure, and the material of the passivation layer 106 uses the material the same to that of the passivation layer 104. In this embodiment, the passivation layer 104 comprises, for example, an organic material. However, the invention is not limited thereto. In other embodiments, the passivation layer 104 and the passivation layer 106 comprise similar materials or different materials. When the passivation layer 106 comprises an organic material, it is referred to as a planar layer. Furthermore, the passivation layers 104, 106 can selectively cover the bonding pad electrode BP.

It should be noted that even though the embodiment is described with the passivation layers 104, 106 formed on the active device T, the invention is not limited thereto. According to other embodiments, only the passivation layer 104 is formed on the active device T and/or the bonding pad electrode BP, or only the passivation layer 106 is formed on the active device T and/or the bonding pad electrode BP.

After forming the passivation layers 104, 106, a first through hole C1 is formed in the passivation layers 104, 106 to expose a portion of the active device T. In detail, the first through hole C1 exposes the drain D of the active device T. In addition, a second through hole C2 is formed in the passivation layers 104, 106 to expose the bonding pad electrode BP. The method of forming the first through hole C1 and the second through hole C2 in the passivation layers 104, 106 adopts, for example, a photolithography and etching process.

Next, the first conductive material 110 is formed in the first through hole C1, and the second conductive material 112 is formed in the second through hole C2. In the embodiment, the first/second conductive materials 110, 112, for example, are formed through a deposition process and a patterning process. The first/second conductive material 110, 120, respectively cover the surface of the first through hole C1 and the surface of the second through hole C2. That is to say, the first/second conductive materials 110, 112, completely cover the bottom of the first/second through holes C1, C2 or partially cover the bottom of the first/second through holes C1, C2. The conductive materials 110, 112 can be a single layer or a multiple layer structure, and the material can be a conductive material (e.g. molybdenum, aluminum, titanium, tantalum, gold, copper, silver, or other suitable materials, or an alloy of the above materials, or a nitride of the above materials, or an oxide of the above materials) or a transparent conductive material (e.g. indium-tin oxide (ITO), indium-zinc oxide (IZO), gallium-zinc oxide (GZO), zinc-tin oxide (ZTO) etc.), and the first/second conductive materials 110, 112 can be formed in the same process or in different processes.

Next, a pixel electrode PE is formed on the passivation layers 104, 106. The pixel electrode PE directly covers the conductive material 110. The pixel electrode PE and the corresponding active device T form a pixel unit P. In addition, a contact pattern 150 is formed on the passivation layers 104, 106. The pixel electrode PE is separated from the contact pattern 150. More particularly, the formed pixel electrode PE and the contact layer 150 are respectively a non-thin-film electrode made up by a plurality of micro-conductive structures. In the embodiment of FIG. 1, the micro-conductive structures are stacked together, for example, as metal wires stacked together or referred to as metal wire segments stacked together or conductive nano-tubes stacked together. In further detail, the metal wires or the conductive nano-tubes are each an independent metal wire or a conductive nano-tube, and are electrically contacted through mutual stacking or contact to become the pixel electrode PE in a single pixel unit P and become a single contact pattern 150.

Furthermore, the pixel electrode PE and the contact pattern 150 are made up by metal wires or conductive nano-tubes, and not formed by conventional film type. Thus the pixel electrode PE and the contact pattern 150 formed by the metal wires or the conductive nano-tubes have better flexibility and ability to extend. When the pixel electrode PE and the contact pattern 150 are used in a flexible display, they will not crack when bent. In addition, because the metal wires forming the pixel electrode PE and the contact pattern 150 are non-thin-film type, the metal wires or the conductive nano-tubes in the first/second through holes C1, C2 may have an insufficient electrical contact area and have the problems of poor electrical contact with the drain D of the active device T and poor electrical contact with the bonding pad electrode BP. Thus, in the embodiment, before forming the pixel electrode PE and the contact pattern 150, the first/second conductive materials 110, 112 are formed in the first/second through holes C1, C2, so the first/second conductive materials 110, 112 are electrically connected to the drain D of the active device T and the bonding pad electrode BP, respectively. Then, after the pixel electrode PE and the contact pattern 150 are formed on the passivation layer 106, the pixel electrode PE and the contact pattern 150 can directly be in electrical contact with the first/second conductive materials 110, 112, respectively. Therefore, the pixel electrode PE is electrically connected to the drain D through the first conductive materials 110, and the contact pattern 150 is electrically connected to the bonding pad electrode BP through the second conductive materials 112.

According to another embodiment, the pixel electrode PE and the contact pattern 150 may also include an organic conductive polymer material.

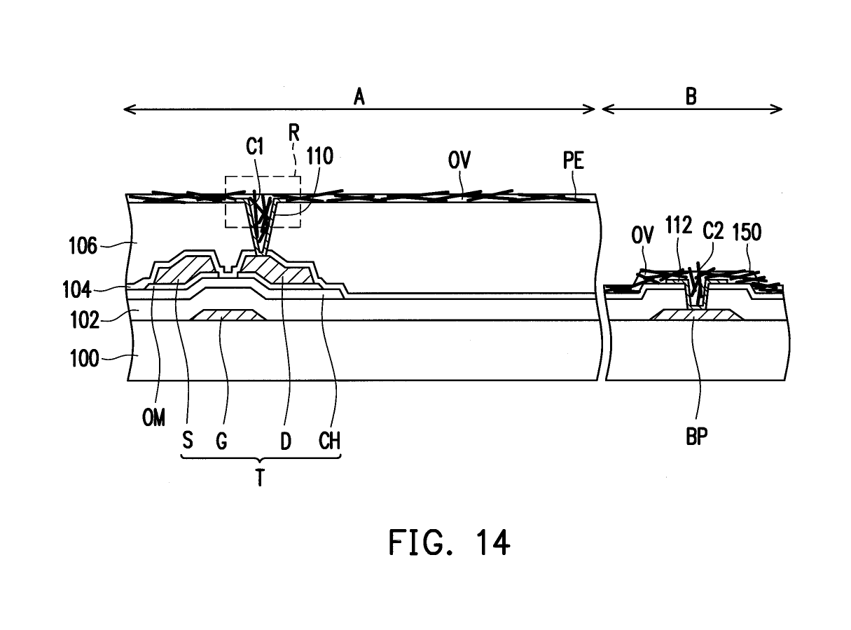

In addition, according to an embodiment of the invention, the pixel electrode PE and the contact pattern 150 further include an adhesive, so as to adhere the micro-conductive structures together. According to another embodiment, the pixel electrode PE and the contact pattern 150 further comprise a cover layer OV to increase adhesion of the micro-conductive structures of the pixel electrode PE and the contact pattern 150, as shown in FIG. 14. The cover layer OV is made of organic material, and is relatively thin. Since the cover layer OV is thin enough, parts of the metal wires (or the metal wire segments) of the pixel electrode PE and the contact pattern 150 may pierce the cover layer OV, such that the cover layer OV will not affect the bonding between the contact pattern 150 and subsequent components.

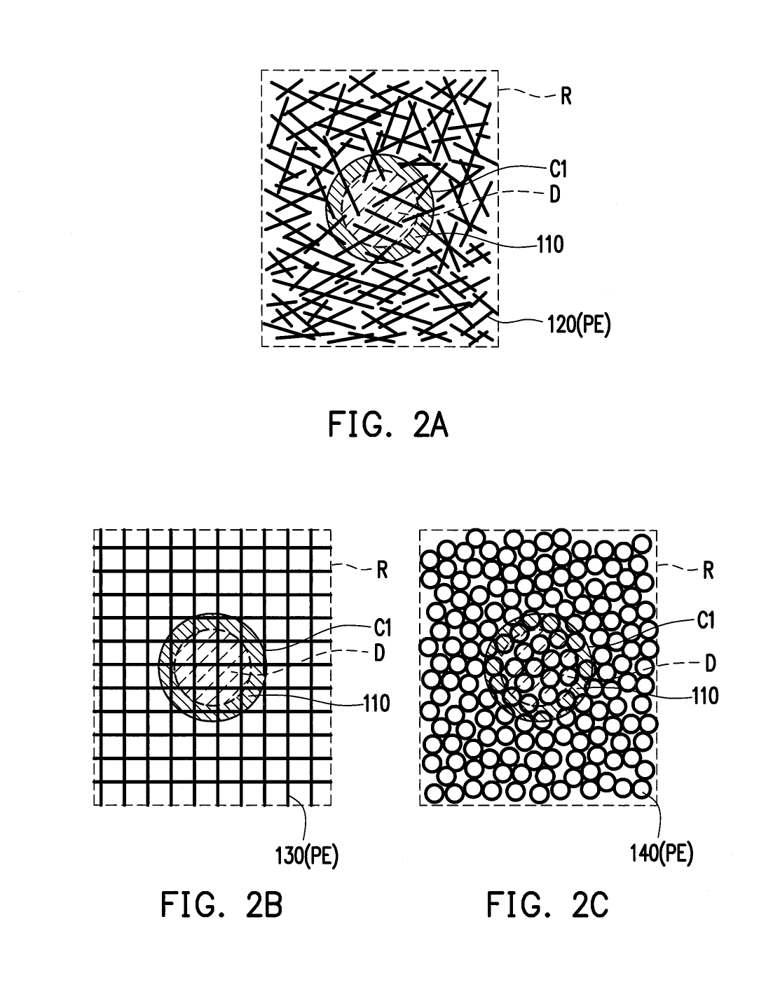

FIG. 2A through FIG. 2C are used in order to describe the assembly structure of the pixel electrode PE and the contact pattern 150 in detail. FIG. 2A through FIG. 2C are schematic top views of the first through hole area (area R) of the corresponding FIG. 1. Referring to FIG. 1 and FIG. 2A, in the embodiment, the first through hole C1 exposes the drain D, and the conductive material 110 is formed in the first through hole C1, and is electrically connected to the drain D. In addition, since the conductive material 110 is directly in electrical contact with the pixel electrode PE, the metal wires 120 forming the pixel electrode PE not only be directly in electrical contact with the drain D in the first through hole C1, it can further be electrically connected with the drain D through the conductive material 110.

In other words, in the embodiment, the conductive material 110 is formed between the pixel electrode PE and the drain D, so the conductive material 110 is formed in the first through hole C1 and is electrically connected to the drain D, to resolve the problem of possible poor electrical contact between the drain D and the metal wires 120 of the pixel electrode PE. Since the conductive material 110 is only formed in or near the first through hole C1, most of the pixel electrode PE in the display device structure are metal wires 120. Thus, the display device still has flexibility.

In the embodiment of FIG. 1 and FIG. 2A, the pixel electrode PE is made up by stacking the metal wires 120. However, the disclosure is not limited to this configuration. According to another embodiment, the pixel electrode PE can also be made up by stacking conductive nano-tubes. In addition, according to other embodiments, the pixel electrode PE can also be made up of other micro-conductive structures, as shown in FIG. 2B and FIG. 2C.

FIG. 2B is a schematic view of the first through hole C1 corresponding to FIG. 1. In the embodiment of FIG. 2B, the micro-conductive structures that make up the pixel electrode PE are metal wires 130 that form a mesh structure. In the embodiment, the pixel electrode PE is a non-thin-film type because it is made up by metal wires 130 constructing a mesh structure. In other words, the pixel electrode PE of the embodiment is made up by the metal mesh structure 130. The pixel electrode PE made up by the metal wires 130 that construct a mesh structure has flexibility. In addition, in the embodiment, the conductive material 110 is formed between the metal wires of the mesh structure 130 (pixel electrode PE) and the drain D, so the conductive material 110 is formed in the first through hole C1 and is electrically connected to the drain D, to resolve the problem of possible poor electrical contact between the drain D and the metal wires of the mesh structure 130 (pixel electrode PE).

FIG. 2C is a schematic view of the first through hole C1 corresponding to FIG. 1. In the embodiment of FIG. 2C, the pixel electrode PE is constructed by nano-particles. The nano-particles or a nano-conductive structure 140 are electrically contacted together through a stacking or contacting method, so as to be the pixel electrode PE in a single pixel unit. Similarly, the pixel electrode PE is constructed to be a non-thin-film type through the nano-particles or the nano-conductive structure 140. Thus, the pixel electrode PE made up by the nano-particles or the nano-conductive structure 140 is flexible. In addition, in the embodiment, the conductive material 110 is also formed between the nano-particles or the nano conductive structure 140 (pixel electrode PE) and the drain D, so the conductive material 110 is formed in the first through hole C1 and is electrically connected to the drain D, to resolve the problem of possible poor electrical contact between the drain D and the nano-particles or nano conductive structure (pixel electrode PE).

The schematic views of FIGS. 2A through 2C depict the structures of the first through hole C1. The structure of the second through hole C2 is identical or similar to the structures shown in FIGS. 2A through 2C.

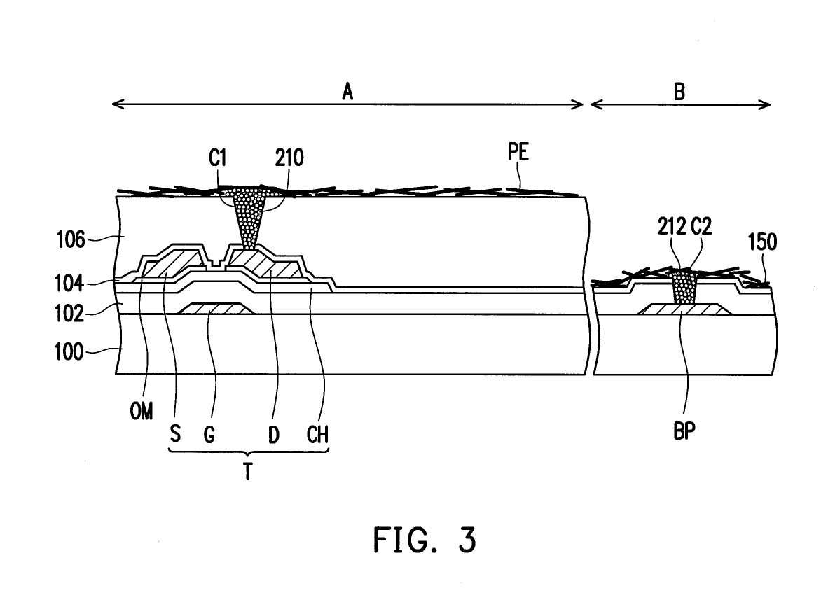

FIG. 3 is a schematic cross-sectional view of a display device according to an embodiment of the invention. Referring to FIG. 3, the embodiment shown in FIG. 3 is similar to the embodiment shown in FIG. 1 so that components identical to those of FIG. 1 will be denoted with the same numerals in FIG. 3 and not repeated herein. In the embodiment, after forming the first/second through holes C1, C2, the first/second conductive materials 210, 212 are filled in the first/second through holes C1, C2, and then the pixel electrode PE/contact pattern 150 are formed on the passivation layer 106. It should be noted that the first/second conductive materials are completely filled (not shown), partially filled (not shown), or filled and extend to part of the surface of the passivation layer 106 (shown in FIG. 3), depending on design requirements. The invention is not limited to any particular type of design. The method of filling the first/second conductive materials 210, 212 in the first/second through holes C1, C2 is through an inkjet printing process or a screen printing process. According to the embodiment, the first/second conductive materials 210, 212 includes conductive ink material containing nano-particles, for example nano-metallic particles, including gold, silver, copper, or other metals; or nano-metallic oxide particles, for example indium-tin oxide (ITO) nano-particles, ZnO SnO nano-particles, indium-zinc oxide (IZO) nano-particles, gallium-zinc oxide (GZO) nano-particles, zinc-tin oxide (ZTO) nano-particles, or other metallic oxide particles. Similarly, since the pixel electrode PE and the contact pattern 150 are non-thin-film electrodes made up by micro-conductive structures, the pixel electrode PE/contact pattern 150 have flexibility. In addition, in the embodiment, before forming the pixel electrode PE/contact pattern 150, the first/second through holes C1, C2 are filled with the first/second conductive materials 210, 212 through the inkjet printing process or the screen printing process so that the conductive materials 210, 212 formed in the through holes C1, C2 are electrically connected to the drain D and the bonding pad electrode BP, to resolve the problems of poor electrical contact between the drain D and the pixel electrode PE and poor electrical contact between the contact pattern 150 and the bonding pad electrode BP.

In addition, according to another embodiment, the pixel electrode PE/contact pattern 150 and the first/second conductive materials 210, 212 can also be done through forming the pixel electrode PE/contact pattern 150 on the passivation layers 104, 106, and then performing the inkjet printing process or screen printing process to fill the first/second through holes C1, C2 with the first/second conductive materials 210, 212. The first/second conductive materials 210, 212 are directly contacted to the pixel electrode PE and the contact pattern 150. Thus, the first/second conductive materials 210, 212 can allow the pixel electrode PE and the drain D of the active device T to be electrically connected, and allow the contact pattern 150 to be electrically connected to the bonding pad electrode BP.

If the first/second conductive materials 210, 212 are filled in the first/second through holes C1, C2, or the first/second conductive materials 210, 212 are filled in the first/second through holes C1, C2 and extend to part of the surface of the passivation layer 106, and then forming the pixel electrode PE and the contact pattern 150 on the passivation layers 104, 106, the pixel electrode PE and the contact pattern 150 will not be filled in the first/second through holes C1, C2. In other words, when the first/second through holes C1, C2 are filled with the first/second conductive materials 210, 212, the pixel electrode PE and the contact pattern 150 are electrically contacted to the first/second conductive materials 210, 212 on the passivation layer 106. When the first/second through holes C1, C2 are filled with the first/second conductive materials 210, 212 and the first/second conductive materials extend to part of the surface of the passivation layer 106, the pixel electrode PE and the contact pattern 150 are in electrical contact with the first/second conductive materials 210, 212 on the first/second through holes C1, C2 and the passivation layer 106.

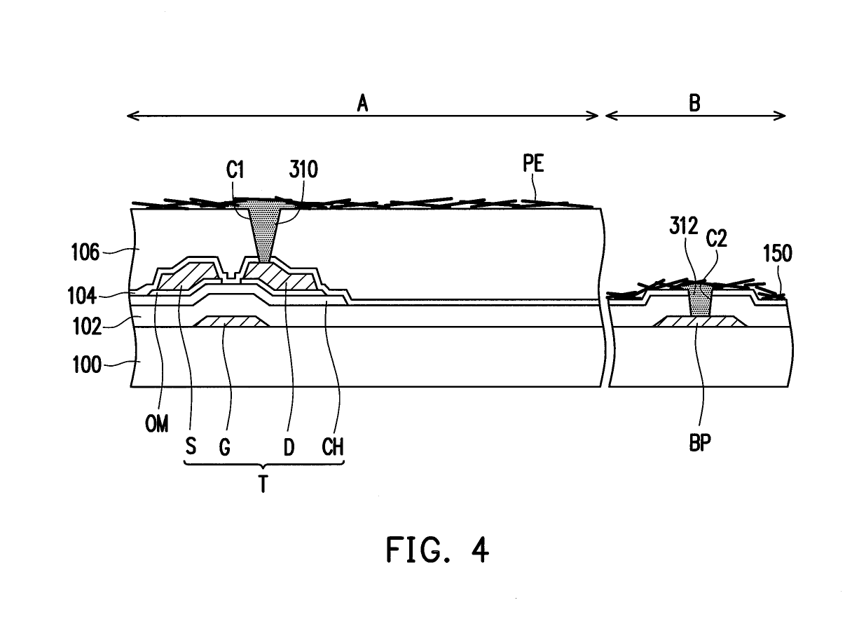

FIG. 4 is a schematic cross-sectional view of a display device according to an embodiment of the invention. Referring to FIG. 4, the embodiment shown in FIG. 4 is similar to the embodiment shown in FIG. 1 so that components identical to those of FIG. 1 will be denoted with the same numerals in FIG. 4 and not repeated herein. In the embodiment, after forming the first/second through holes C1, C2, the pixel electrode PE/contact pattern 150 are formed on the passivation layer 106. It should be noted that the first/second conductive materials 310, 312 are completely filled (not shown), partially filled (not shown), or the first/second conductive materials 210, 212 are filled and extend to part of the surface of the passivation layer 106 (shown in FIG. 4), depending on design requirements. The method of filling the first/second conductive materials 310, 312 in the first/second through holes C1, C2 is through an inkjet printing process or a screen printing process. According to the embodiment, the first/second conductive materials 310, 312 includes organic conductive material, for example, 3, 4-polyethylenedioxythiphene: polystyrenesulfonate, PEDOT: PSS, polyaniline, polyacetylene, polypyrrole, polythiophene, or other suitable organic conducitve materials. Similarly, since the pixel electrode PE and the contact pattern 150 are non-thin-film electrodes made up by micro-conductive structures, the pixel electrode PE and the contact pattern 150 have flexibility. In addition, in the embodiment, before forming the pixel electrode PE and the contact pattern 150, the first/second through holes C1, C2 are filled with the first/second conductive materials 310, 312 through the inkjet printing process or the screen printing process, to resolve the problems of poor electrical contact between the drain D and the pixel electrode PE and poor electrical contact between the contact pattern 150 and the bonding pad electrode BP.

In addition, according to another embodiment, the pixel electrode PE/contact pattern 150 and the first/second conductive materials 310, 312 can also be formed through forming the pixel electrode PE and the contact pattern 150 on the passivation layers 104, 106, and then performing the inkjet printing process or screen printing process to fill the first/second through holes C1, C2 with the first/second conductive materials 310, 312. The first/second conductive materials 310, 312 are directly contacted to the pixel electrode PE and the contact pattern 150. Thus, the first/second conductive materials 310, 312 can allow the pixel electrode PE to be electrically connected the drain D of the active device T, and also allow the contact pattern 150 to be electrically connected the bonding pad P.

If the first/second through holes C1, C2 are filled with the first/second conductive materials 310, 312 and then the pixel electrode PE/contact pattern 150 are formed on the passivation layers 104, 106, the pixel electrode PE and the contact pattern 150 will not be filled in the first/second through holes C1, C2. In other words, when the first/second through holes C1, C2 are filled with the first/second conductive materials 310, 312, the pixel electrode PE and the contact pattern 150 are electrically contacted to the first/second conductive materials 310, 312 on the first/second through holes C1, C2. When the first/second through holes C1, C2 are filled with the first/second conductive materials 310, 312 and the first/second conductive materials 310, 312 extend to part of the surface of the passivation layer 106, the pixel electrode PE and the contact pattern 150 are in electrical contact with the first/second conductive materials 310, 312 on the first/second through holes C1, C2 and the passivation layer 106.

It should be noted that in the embodiments of FIG. 3 and FIG. 4, the pixel electrode PE is described as being stacked metal wires or the conductive nano-tubes 120. However, the disclosure is not limited to this configuration. According to other embodiments, the pixel electrode PE/contact pattern 150 can also be made up of other micro-conductive structures. In other words, in the embodiments of FIG. 3 and FIG. 4, the pixel electrode PE/contact pattern 150 can also be made up by the metal wire mesh structure of FIG. 2B, or by the nano-particles or nano-conductive structure of FIG. 2C. According to another embodiment, the pixel electrode PE/contact pattern 150 comprises an organic conductive polymer material.

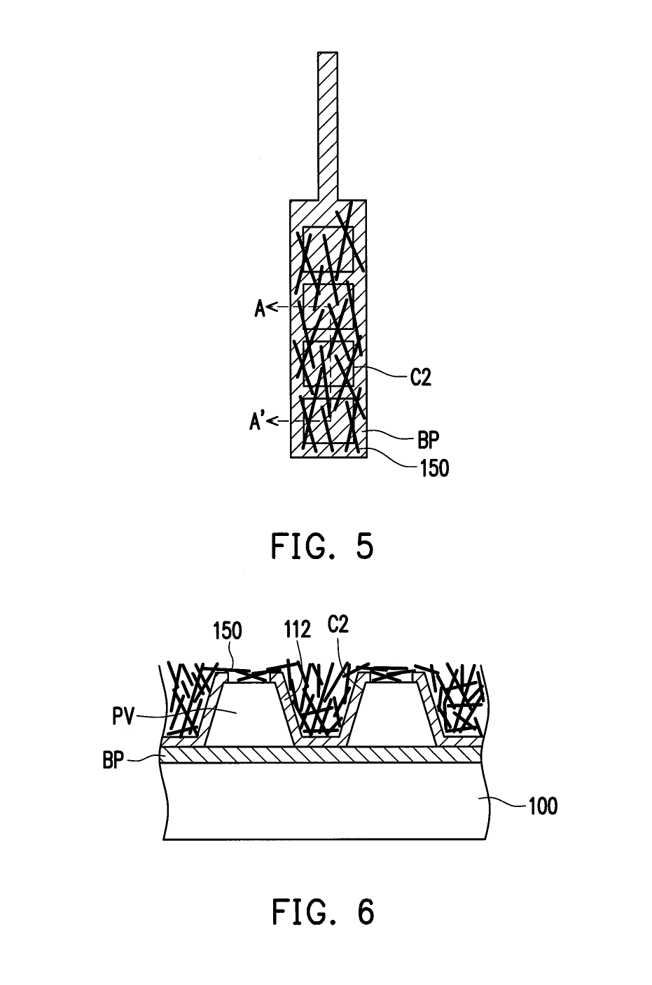

The invention does not limit the structure of the bonding area B to the embodiments of FIGS. 1, 3, and 4. The structure of the bonding area B can also be explained in FIGS. 5-8.

FIG. 5 is a schematic top view of a bonding pad electrode structure according to an embodiment of the invention. FIG. 6 is a schematic cross-sectional view taken along a sectional line A-A′ depicted in FIG. 5. Referring to FIG. 5 and FIG. 6, the bonding pad electrode BP is covered by a passivation layer PV. The passivation layer PV can include the passivation layer 104 and the insulating layer 102 of the previous embodiments, or only one of the passivation layer 104 and the insulating layer 102. In other words, the passivation layer PV is an insulating material covering the bonding pad electrode BP. The passivation layer PV on the bonding pad electrode BP has a plurality of through holes C2, exposing the bonding pad electrode BP.

Similarly, the second conductive material 112 covers the surface of the through hole C2, and the conductive material 112 can completely cover the bottom of the through hole C2 or partially cover the bottom of the through hole C2, so as to electrically connect the drain D. The conductive material 112 can be a single layer or a multiple layer structure, and the material thereof can be a conductive material (e.g. molybdenum, aluminum, titanium, tantalum, gold, copper, silver, or other suitable materials, or an alloy of the above materials, or a nitride of the above materials, or an oxide of the above materials) or a transparent conductive material (e.g. indium-tin oxide (ITO), indium-zinc oxide (IZO), gallium-zinc oxide (GZO), zinc-tin oxide (ZTO) etc.).

In addition, the contact pattern 150 is formed on the second conductive material 112, and the contact pattern 150 is a non-thin-film electrode made up by a plurality of micro-conductive structures. In the embodiment of FIGS. 5 and 6, the micro-conductive structures are metal wires/segments stacked together. In further detail, the metal wires are each an independent metal wire, and are electrically contacted through mutual stacking or contact to become a single contact pattern 150. In addition to the metal wires, the contact pattern 150 may be made up by a plurality of conductive nano-tubes stacked together, metal mesh structure formed of metal wires, or conductive nano-particles.

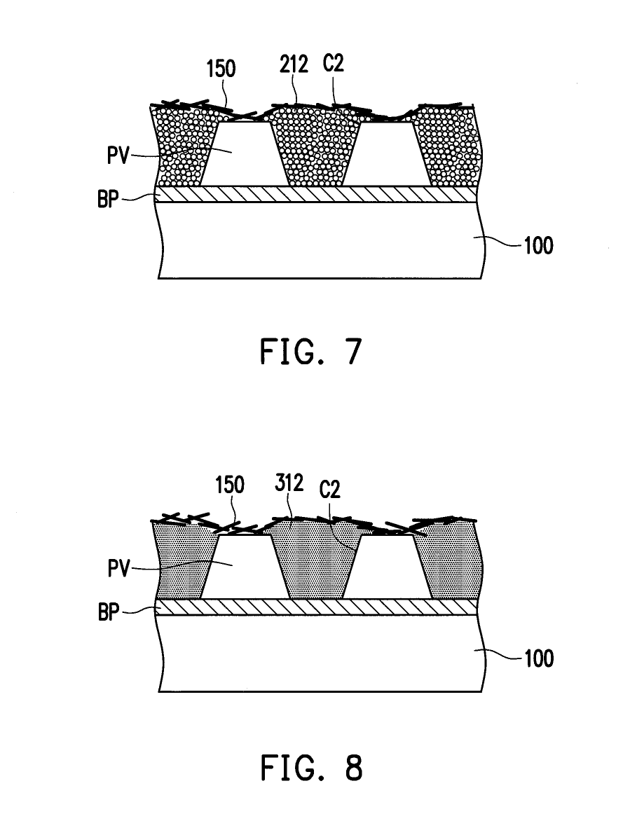

FIG. 7 is a schematic top view of a bonding pad electrode structure according to an embodiment of the invention. Referring to FIG. 7, the embodiment shown in FIG. 7 is similar to the embodiment shown in FIG. 6 so that components identical to those of FIG. 6 will be denoted with the same numerals in FIG. 7 and not repeated herein. In the embodiment, after forming the through hole C2, the through hole C2 is filled with the second conductive material 212, and then the contact pattern 150 is formed on the passivation layer PV. It should be noted that the second conductive material 212 is completely filled (not shown), partially filled (not shown), or filled and extends to part of the surface of the passivation layer PV (shown in FIG. 7), depending on design requirements. The second conductive material 212 is filled in the second through hole C2 by an inkjet printing process or a screen printing process. The second conductive material 212 includes conductive ink material containing nano-particles, for example nano-metallic particles, including gold, silver, copper, or other metals; or nano-metallic oxide particles, for example indium-tin oxide (ITO) nano-particles, ZnO SnO nano-particles, indium-zinc oxide (IZO) nano-particles, gallium-zinc oxide (GZO) nano-particles, zinc-tin oxide (ZTO) nano-particles, or other metallic oxide particles. In addition, the contact pattern 150 and the second conductive material 212 can also be formed by forming the contact pattern 150 on the passivation layer PV, and then performing the inkjet printing process or screen printing process to fill the second through hole C2 with the second conductive material 212.

FIG. 8 is a schematic cross-sectional view of a display device according to an embodiment of the invention. Referring to FIG. 8, the embodiment shown in FIG. 8 is similar to the embodiment shown in FIG. 6 so that components identical to those of FIG. 6 will be denoted with the same numerals in FIG. 8 and not repeated herein. In the embodiment, after forming the through hole C2, the second conductive material 312 is filled in the through hole C2, and then the contact pattern 150 is formed on the passivation layer PV. It should be noted that the second conductive material 312 is completely filled (not shown), partially filled (not shown), or filled and extends to part of the surface of the passivation layer PV (shown in FIG. 8), depending on design requirements. The second conductive material 312 is filled in the second through hole C2 through an inkjet printing process or a screen printing process. According to the embodiment, the second conductive material 312 includes organic conductive material, for example, 3, 4-polyethylenedioxythiphene: polystyrenesulfonate, PEDOT: PSS, polyaniline, polyacetylene, polypyrrole, polythiophene, or other suitable organic conducitve materials. In addition, the contact pattern 150 and the second conductive material 312 can also be formed by forming the contact pattern 150 on the passivation layer PV, and then performing the inkjet printing process or screen printing process to fill the second through hole C2 with the second conductive material 312.

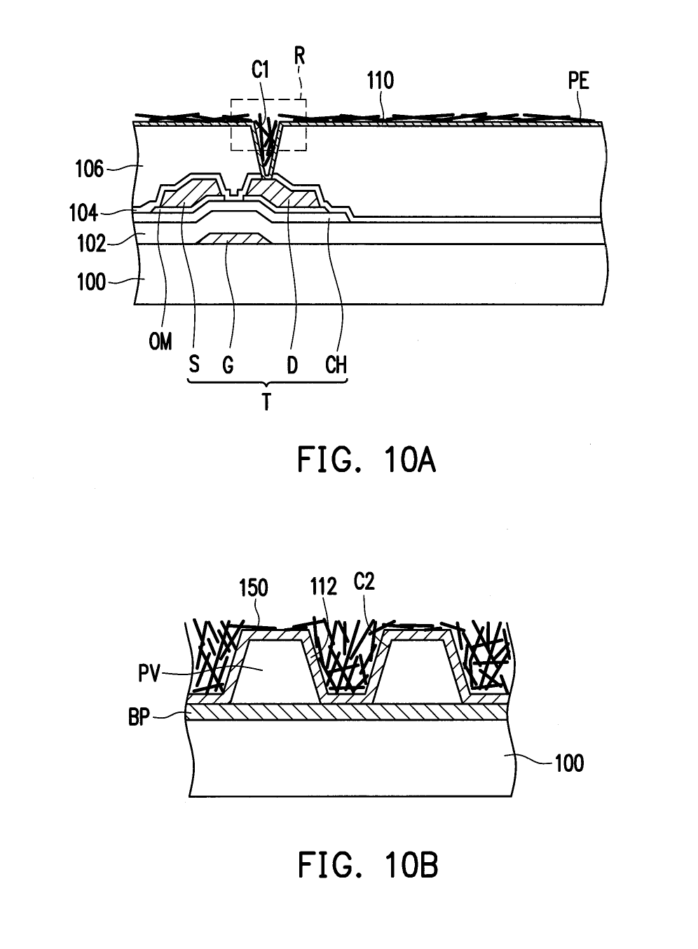

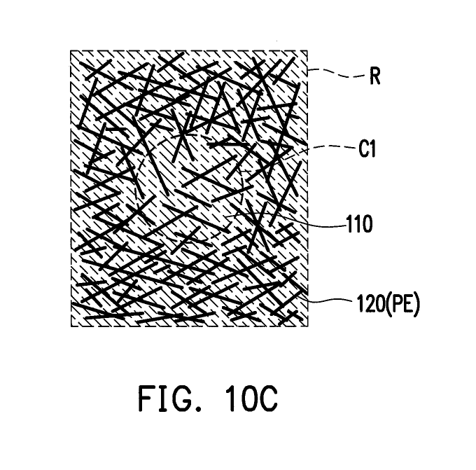

FIG. 10A is a schematic cross-sectional view of a display device structure in a display region according to an embodiment of the invention. FIG. 10B is a schematic cross-sectional view of a display device structure in a bonding region according to an embodiment of the invention. FIG. 10C is a schematic top view showing a display device structure in a region R of FIG. 10A. Referring to FIG. 10A, FIG. 10B and FIG. 10C, the embodiment is similar to the embodiment shown in FIG. 1 so that components identical to those of FIG. 1 will be denoted with the same numerals and not repeated herein. In the embodiment, in the display region (as shown in FIG. 10A), the first conductive material 110 further extends to the outside of the first through hole C1, such that the pixel electrode PE and the first conductive material 110 have the same pattern, as shown in FIG. 10C, the region R is completely covered by the first conductive material 110 and the pixel electrode PE. In addition, in the bonding region (as shown in FIG. 10B), the second conductive material 112 covers the passivation layer PV, where the passivation layer PV may include the passivation layer 104 and the insulating layer 102 or only one of the passivation layer 104 and the insulating layer 102. The second conductive material 112 and the contact pattern 150 have the same pattern. In the embodiment, the pixel electrode PE and the contact pattern 150 are made of metal wires stacked together, metal segments stacked together or conductive nano-tubes stacked together. In further detail, the metal wires/metal segments or the conductive nano-tubes are each an independent metal wire/metal segment or a nano-tube, and are electrically contacted through mutual stacking or contact to become the pixel electrode PE in a single pixel unit P and become a single contact pattern 150.

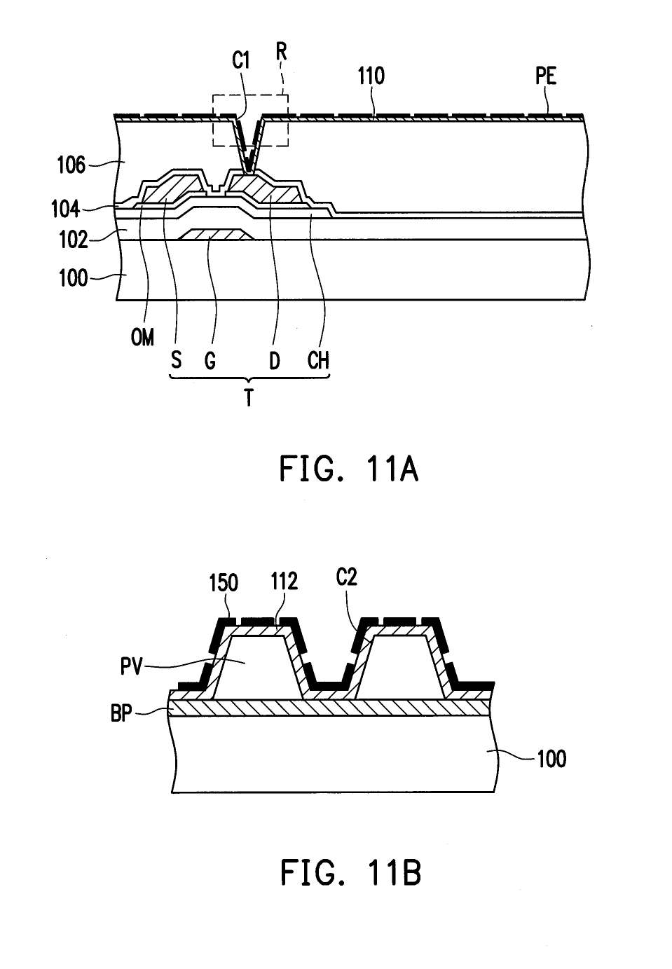

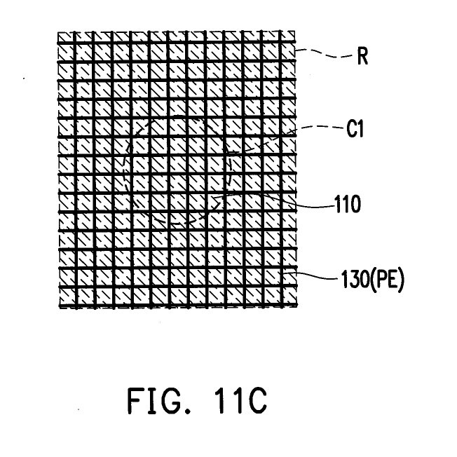

FIG. 11A is a schematic cross-sectional view of a display device structure in a display region according to an embodiment of the invention. FIG. 11B is a schematic cross-sectional view of a display device structure in a bonding region according to an embodiment of the invention. FIG. 11C is a schematic top view showing a display device structure in a region R of FIG. 11A. Referring to FIG. 11A, FIG. 11B and FIG. 11C, the embodiment is similar to the embodiment shown in FIG. 1 so that components identical to those of FIG. 1 will be denoted with the same numerals and not repeated herein. In the embodiment, in the display region (as shown in FIG. 11A), the first conductive material 110 further extends to the outside of the first through hole C1, such that the pixel electrode PE and the first conductive material 110 have the same pattern, as shown in FIG. 11C, the region R is completely covered by the first conductive material 110 and the pixel electrode PE. In addition, in the bonding region (as shown in FIG. 11B), the second conductive material 112 covers the passivation layer PV, where the passivation layer PV may include the passivation layer 104 and the insulating layer 102 or only one of the passivation layer 104 and the insulating layer 102. The second conductive material 112 and the contact pattern 150 have the same pattern. In the embodiment, the pixel electrode PE and the contact pattern 150 are made of a mesh structure formed of metal wires 130.

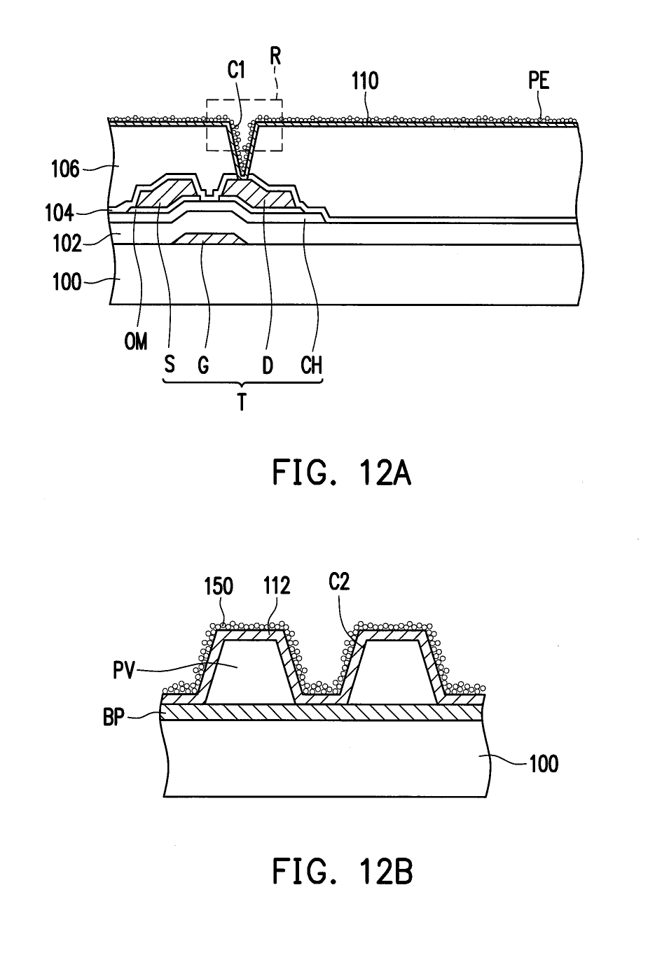

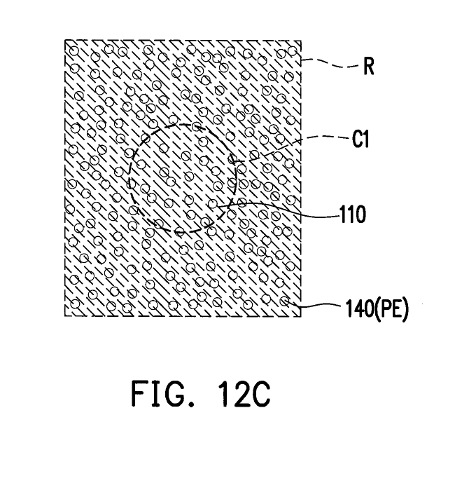

FIG. 12A is a schematic cross-sectional view of a display device structure in a display region according to an embodiment of the invention. FIG. 12B is a schematic cross-sectional view of a display device structure in a bonding region according to an embodiment of the invention. FIG. 12C is a schematic top view showing a display device structure in a region R of FIG. 12A. Referring to FIG. 12A, FIG. 12B and FIG. 12C, the embodiment is similar to the embodiment shown in FIG. 1 so that components identical to those of FIG. 1 will be denoted with the same numerals and not repeated herein. In the embodiment, in the display region (as shown in FIG. 12A), the first conductive material 110 further extends to the outside of the first through hole C1, such that the pixel electrode PE and the first conductive material 110 have the same pattern, as shown in FIG. 12C, the region R is completely covered by the first conductive material 110 and the pixel electrode PE. In addition, in the bonding region (as shown in FIG. 12B), the second conductive material 112 covers the passivation layer PV, where the passivation layer PV may include the passivation layer 104 and the insulating layer 102 or only one of the passivation layer 104 and the insulating layer 102. The second conductive material 112 and the contact pattern 150 have the same pattern. In the embodiment, the pixel electrode PE and the contact pattern 150 are made of conductive nano-particles 130 stacked together or conductive nano-structures 130.

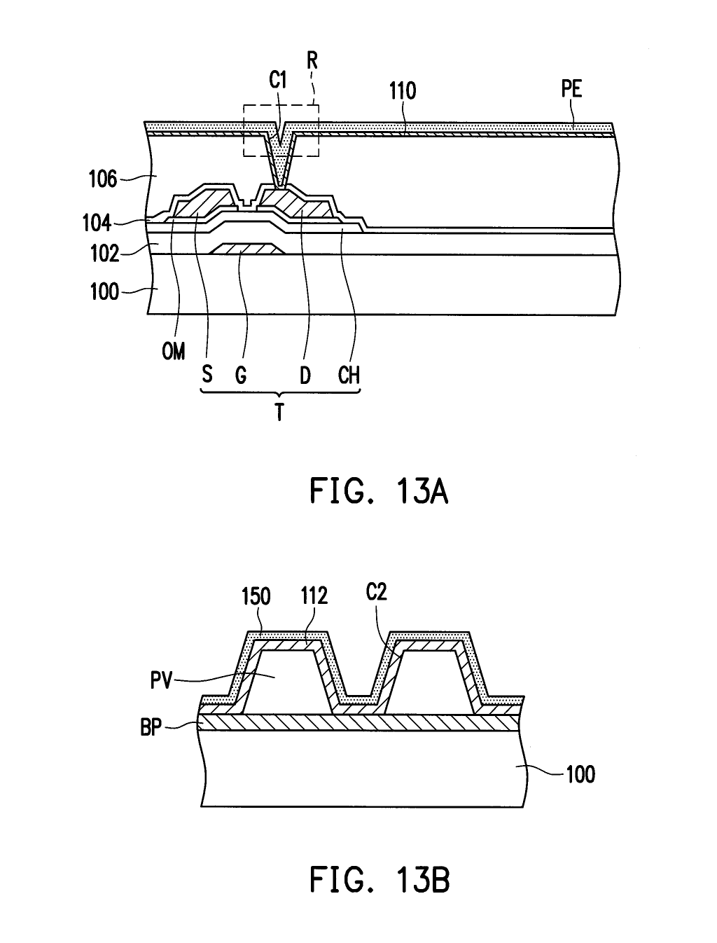

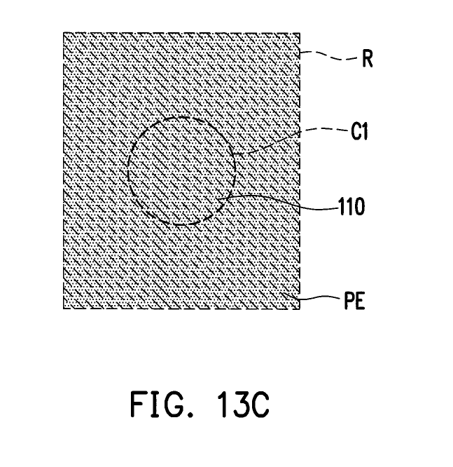

FIG. 13A is a schematic cross-sectional view of a display device structure in a display region according to an embodiment of the invention. FIG. 13B is a schematic cross-sectional view of a display device structure in a bonding region according to an embodiment of the invention. FIG. 13C is a schematic top view showing a display device structure in a region R of FIG. 13A. Referring to FIG. 13A, FIG. 13B and FIG. 13C, the embodiment is similar to the embodiment shown in FIG. 1 so that components identical to those of FIG. 1 will be denoted with the same numerals and not repeated herein. In the embodiment, in the display region (as shown in FIG. 13A), the first conductive material 110 further extends to the outside of the first through hole C1, such that the pixel electrode PE and the first conductive material 110 have the same pattern, as shown in FIG. 13C, the region R is completely covered by the first conductive material 110 and the pixel electrode PE. In addition, in the bonding region (as shown in FIG. 13B), the second conductive material 112 covers the passivation layer PV, where the passivation layer PV may include the passivation layer 104 and the insulating layer 102 or only one of the passivation layer 104 and the insulating layer 102. The second conductive material 112 and the contact pattern 150 have the same pattern. In the embodiment, the pixel electrode PE and the contact pattern 150 includes an organic conductive polymer material.

In the foregoing embodiments, the pixel electrode PE and the contact pattern 150 respectively are a non-thin-film electrode constituted by a plurality of micro-conductive structures or include an organic conductive polymer material, and the micro-conductive structures include metal wires stacked together, conductive nano-tubes stacked together, a mesh structure formed of metal wires, or conductive nano-particles. The invention does not limit that the pixel electrode PE and the contact pattern 150 are formed from a single type of micro-conductive structures. Namely, the pixel electrode PE and the contact pattern 150 may also be formed by (a) metal wires stacked together, (b) conductive nano-tubes stacked together, (c) a mesh structure formed of metal wires, (d) conductive nano-particles, (e) an organic conductive polymer material, or a combination thereof. In particular, said combination may be a stacked layer or a hybrid layer formed from at least two of (a) metal wires stacked together, (b) conductive nano-tubes stacked together, (b) a mesh structure formed of metal wires, (d) conductive nano-particles, and (e) an organic conductive polymer material. For instance, the pixel electrode PE and the contact pattern 150 are formed from stacking a layer of metal wires and a layer of conductive nano-particles. In another embodiment, the pixel electrode PE and the contact pattern 150 may also be a hybrid layer in which conductive nano-tubes and conductive nano-particles are mixed.

Table 1 shows many combinations which adapting two materials to form the pixel electrode PE and the contact pattern 150.

TABLE 1

| combination | |
|---|---|
| 1 | a stacking layer or a hybrid layer with (a) + (b) |
| 2 | a stacking layer or a hybrid layer with (a) + (c) |
| 3 | a stacking layer or a hybrid layer with (a) + (d) |
| 4 | a stacking layer or a hybrid layer with (a) + (e) |
| 5 | a stacking layer or a hybrid layer with (b) + (c) |
| 6 | a stacking layer or a hybrid layer with (b) + (d) |
| 7 | a stacking layer or a hybrid layer with (b) + (e) |
| 8 | a stacking layer or a hybrid layer with (c) + (d) |
| 9 | a stacking layer or a hybrid layer with (c) + (e) |
| 10 | a stacking layer or a hybrid layer with (d) + (e) |

Table 1 only shows a stacking layer or a hybrid layer with two of (a) metal wires stacked together, (b) conductive nano-tubes stacked together, (b) a mesh structure formed of metal wires, (d) conductive nano-particles, and (e) an organic conductive polymer material to form the pixel electrode PE and the contact pattern 150, but the invention is not limited to these combinations. According to other embodiments, the pixel electrode PE and the contact pattern 150 may be a stacked layer or a hybrid layer formed from three, four or five of (a) metal wires stacked together, (b) conductive nano-tubes stacked together, (b) a mesh structure formed of metal wires, (d) conductive nano-particles, and (e) an organic conductive polymer material.

Generally, the invention adopts the non-thin-film electrode formed by micro-conductive structures or the organic conductive polymer material as the pixel electrode/contact pattern, the pixel electrode is electrically connected to the active device through the first conductive material, and the contact pattern is electrically connected to the bonding pad electrode through the second conductive material. Since the pixel electrode/contact pattern that is a non-thin-film electrode formed by micro-conductive structures or the organic conductive polymer material is flexible, when applied in a flexible display, there will be no cracking problem.

Furthermore, in the invention, since the pixel electrode is electrically connected to the active device through the first conductive material and the contact pattern is electrically connected to the bonding pad electrode through the second conductive material, the pixel electrode/contact pattern will have no problem being in electrical contact with the active device/bonding pad electrode even though they are a non-thin-film electrode.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A display device structure, comprising:
an active device;
a passivation layer, covering the active device, wherein the passivation layer has a first through hole exposing a portion of the active device;
a pixel electrode, disposed on the passivation layer, wherein the pixel electrode comprises an organic conductive polymer material; and
a first conductive material, disposed around the first through hole and electrically connected to the exposed active device, wherein the pixel electrode is electrically connected to the first conductive material.

2. The display device structure as claimed in claim 1, wherein the pixel electrode further comprises a non-thin-film pattern made up by a plurality of micro-conductive structures, and the micro-conductive structures include metal wires stacked together, conductive nano-tubes stacked together, a mesh structure formed of metal wires, conductive nano-particles, or a combination thereof.

3. The display device structure as claimed in claim 2, wherein the pixel electrode is a stacking layer or a hybrid layer formed from at least two of the metal wires stacked together, the conductive nano-tubes stacked together, the mesh structure formed of metal wires, the conductive nano-particles, and the organic conductive polymer material.

4. The display device structure as claimed in claim 1, wherein the pixel electrode further comprises an adhesive.

5. The display device structure as claimed in claim 1, further comprising a cover layer, at least partially covering the pixel electrode.

6. The display device structure as claimed in claim 1, wherein the first conductive material covers a surface of the first through hole, and the pixel electrode covers the first conductive material.

7. The display device structure as claimed in claim 1, wherein the first conductive material is filled in the first through hole.

8. The display device structure as claimed in claim 1, wherein the pixel electrode is filled in the first through hole and is electrically connected to the first conductive material, or is not filled in the first through hole and is electrically connected to the first conductive material on a surface of the passivation layer.

9. The display device structure as claimed in claim 1, wherein the first conductive material includes an organic conductive material, a conductive ink material containing nano-particles, a metal material, or a metallic oxide material.

10. The display device structure as claimed in claim 1, wherein the first conductive material further extends out of the first through hole such that the pixel electrode and the first conductive material have the same pattern.

11. The display device structure as claimed in claim 1, wherein the first conductive material is disposed under the pixel electrode.

12. The display device structure as claimed in claim 1, further comprising:
a bonding pad;
the passivation layer covering the bonding pad, wherein the passivation layer has at least one second through hole exposing the bonding pad;
a contact pattern, disposed on the passivation layer, wherein the contact pattern is a non-thin-film pattern made up by a plurality of micro-conductive structures or includes an organic conductive polymer material; and
a second conductive material, disposed around the second through hole and electrically connected to the exposed bonding pad, wherein the contact pattern is electrically connected to the second conductive material.

13. The display device structure as claimed in claim 12, wherein the micro-conductive structures include metal wires stacked together, conductive nano-tubes stacked together, a mesh structure formed of metal wires, conductive nano-particles, or a combination thereof.

14. The display device structure as claimed in claim 12 wherein the contact pattern is a stacking layer or a hybrid layer formed from at least two of metal wires stacked together, conductive nano-tubes stacked together, mesh structure formed of metal wires, conductive nano-particles, and the organic conductive polymer material.

15. A method for manufacturing a display device structure, comprising:
forming an active device on a substrate;
forming a passivation layer on the substrate to cover the active device;
forming a first through hole in the passivation layer to expose a portion of the active device;
forming a pixel electrode on the passivation layer, wherein the pixel electrode comprises an organic conductive polymer material; and
forming a first conductive material around the first through hole, wherein the first conductive material is electrically connected to the exposed active device, and the pixel electrode is electrically connected to the first conductive material.

16. The method as claimed in claim 15, wherein the pixel electrode further comprises a non-thin-film pattern made up by a plurality of micro-conductive structures, and the plurality of micro-conductive structures include metal wires stacked together, conductive nano-tubes stacked together, a mesh structure formed of metal wires, or conductive nano-particles, or a combination thereof.

17. The method as claimed in claim 15, wherein the contact pattern is a stacking layer or a hybrid layer formed from at least two of metal wires stacked together, conductive nano-tubes stacked together, mesh structure formed of metal wires, conductive nano-particles, and the organic conductive polymer material.

18. The method as claimed in claim 15, wherein the pixel electrode further comprises an adhesive.

19. The method as claimed in claim 15, further comprising forming a cover layer on the pixel electrode.

20. The method as claimed in claim 15, wherein the method of forming the pixel electrode and forming the first conductive material comprises:
forming the first conductive material on a surface of the first through hole; and
forming the pixel electrode on the passivation layer after forming the first conductive material, wherein the pixel electrode is electrically connected to the first conductive material.

21. The method as claimed in claim 15, wherein the pixel electrode is filled in the first through hole and is electrically connected to the first conductive material, or is not filled in the first through hole and is electrically connected to the first conductive material on a surface of the passivation layer.

22. The method as claimed in claim 21, wherein the first conductive material comprises a metallic material or a metal oxide material.

23. The method as claimed in claim 15, wherein the method of forming the pixel electrode and forming the first conductive material comprises:
filling the first through hole with the first conductive material; and
forming the pixel electrode on the passivation layer after forming the first conductive material, wherein the pixel electrode is electrically connected to the first conductive material.

24. The method as claimed in claim 23, wherein the method of forming the first conductive material comprises performing an inkjet printing process or a screen printing process.

25. The method as claimed in claim 23, wherein the first conductive material comprises an organic conductive material or a conductive ink material containing nano-particles.

26. The method f as claimed in claim 23, wherein the pixel electrode is filled in the first through hole, or is not filled in the first through hole.

27. The method as claimed in claim 15, wherein the method of forming the pixel electrode and forming the first conductive material comprises:
forming the pixel electrode on the passivation layer; and
filling the first through hole with the first conductive material after forming the pixel electrode, wherein the pixel electrode is electrically connected to the first conductive material.

28. The method as claimed in claim 27, wherein the method of forming the first conductive material comprises performing an inkjet printing process or a screen printing process.

29. The method as claimed in claim 24 wherein the first conductive material comprises an organic conductive material or a conductive ink material containing nano-particles.

30. The method as claimed in claim 24 wherein the pixel electrode is filled in the first through hole, or is not filled in the first through hole.

31. The method as claimed in claim 15, further comprising:
forming a bonding pad on the substrate;
the bonding pad is covered by the passivation layer, wherein the passivation layer has at least one second through hole exposing the bonding pad;
forming a contact pattern on the passivation layer, wherein the contact pattern is a non-thin-film pattern constituted by a plurality of micro-conductive structures or includes an organic conductive polymer material; and
forming a second conductive material in the second through hole, wherein the second conductive material is electrically connected to the exposed bonding pad, and the contact pattern is electrically connected to the second conductive material.

32. The method as claimed in claim 15, wherein the first conductive material further extends out of the first through hole such that the pixel electrode and the first conductive material have the same pattern.

33. The method as claimed in claim 32, wherein the first conductive material and the pixel electrode are formed by forming the first conductive material and then forming the pixel electrode, or forming the pixel electrode and then forming the first conductive material.

34. A bonding pad structure, comprising:
a bonding pad;
a passivation layer covering the bonding pad, wherein the passivation layer has at least one through hole exposing the bonding pad;
a contact pattern, disposed on the passivation layer, wherein the contact pattern is a non-thin-film pattern made up by a plurality of micro-conductive structures; and
a conductive material, disposed around the through hole and electrically connected to the exposed bonding pad, wherein the contact pattern is electrically connected to the conductive material.

35. The bonding pad structure as claimed in claim 34, wherein the micro-conductive structures include metal wires stacked together, conductive nano-tubes stacked together, a mesh structure formed of metal wires, conductive nano-particles, or a combination thereof.

36. The bonding pad structure as claimed in claim 35, wherein the contact pattern further comprises an organic conductive polymer material, and the contact pattern is a stacking layer or a hybrid layer formed from at least two of the metal wires stacked together, the conductive nano-tubes stacked together, the mesh structure formed of metal wires, the conductive nano-particles, and the organic conductive polymer material.

37. The bonding pad structure as claimed in claim 34, wherein the contact patter further comprises an adhesive.

38. The bonding pad structure as claimed in claim 34, further comprising a cover layer, at least partially covering the contact pattern.

39. The bonding pad structure as claimed in claim 34, wherein the conductive material is filled in the through hole.

40. The bonding pad structure as claimed in claim 34, wherein the conductive material covers a surface of the through hole, and the contact pattern covers the conductive material.

41. The bonding pad structure as claimed in claim 34, wherein the contact pattern is filled in the through hole and is electrically connected to the conductive material, or is not filled in the through hole and is electrically connected to the conductive material on a surface of the passivation layer.

42. The bonding pad structure as claimed in claim 34, wherein the conductive material further extends out of the through hole such that the contact pattern and the conductive material have the same pattern.

43. The bonding pad structure as claimed in claim 34, wherein the conductive material is disposed under the contact pattern.
